(19) United States
(12) Patent Application Publication
(10) Pub. No.: US 2011/0237048 A1
(43) Pub. Date: Sep. 29, 2011

(54) METHOD FOR MANUFACTURING A FULL SILICIDATION METAL GATE

(76) Inventors: Huajie Zhou, Beijing (CN); Qiuxia Xu, Beijing (CN)

(21) Appl. No.: 12/990,042

(22) PCT Filed: Jun. 28, 2010
(86) PCT No.: PCT/CN10/74603

§ 371 Date: Oct. 28, 2010

(30) Foreign Application Priority Data
Dec. 2, 2009 (CN) 200910241686.2

(51) Int. Cl. H01L 21/762; B82Y 40/00

(52) U.S. Cl. 438/439; 977/840; 257/E21.552

(57) ABSTRACT

The present application discloses a method for manufacturing a full silicidation metal gate, comprises the steps of forming locally oxidized isolation or shallow trench isolation, performing prior-implantation oxidation and then doping ¹⁴N⁺; removing the prior-implantation oxidation layer formed before ion implantation, performing gate oxidation, and depositing a polysilicon layer; performing lithography and etching to form a gate electrode of polysilicon; implanting and activating dopants; depositing metal such as Ni; performing a first annealing so that Ni reacts with a portion of polysilicon; selectively removing unreacted Ni; performing a second annealing so that the whole gate electrode is converted into nickel silicide to form a full silicidation metal gate electrode. The present invention provides a full silicidation metal gate electrode which overcomes the disadvantages of polysilicon gate electrode.

### BACKGROUND OF THE INVENTION

1. Field of Invention

The present invention relates to a complementary Metal-Oxide-Semiconductor (CMOS) device of ultra-deep submicron technology and very large scale integration (VLSI) of microelectronics, and specifically, to a method of manufacturing a full silicidation metal gate for the CMOS device and circuit of ultra-deep submicron technology.

2. Description of Prior Art

Since the first transistor was invented, transistors have being exploited for half a century and have being approached to reduced lateral and longitudinal dimensions. As predicted by International Technology Roadmap for Semiconductors (ITRS), the feature size of the transistor will reach 7 nm in 2018. Continuous reduction of the feature size causes continuous improvement of performance (for example, the speed) of transistors, and makes it possible to integrate more devices in a single chip having the same area. Thus, the functionality of the integrated circuit is enhanced while product cost is reduced.

In the development of the integrated circuit, polysilicon has been used as the gate electrode for about forty years. However, a transistor having a conventional polysilicon gate will suffer an depletion effect of polysilicon, a boron penetration effect of the PMOS device and a too-high gate resistance after it is scaled down to some extent, which prevent further improvements of the transistor performance and become bottlenecks of the development of CMOS devices.

To solve these problems, the researchers have carried out a great deal of research on candidates for the polysilicon gate. The metal gate is believed to be the most promising candidate. Using metal as a gate electrode eliminates the depletion effect of polysilicon, and the boron penetration effect of PMOS device, and also achieves a very low gate sheet resistance.

In various manufacturing methods of metal gates, the full silicidation metal gate process is relatively simple and compatible with the conventional CMOS process. The early full silicidation metal gate process typically includes one-step annealing, which is a relatively simple process because of the silicidation of the whole gate electrode is achieved in the one annealing. However, the one-step annealing process has the disadvantages of having a non-uniform silicide layer and introducing a linewidth effect.

### SUMMARY OF THE INVENTION

It is an object of the present invention to provide a method for providing a full silicidation metal gate overcoming the disadvantages of the one-step annealing process.

To achieve the above object, the inventive method comprises the steps of

1) forming locally oxidized isolation or shallow trench isolation, prior-implantation oxidation and then doping ¹⁴N⁺;

2) removing the prior-implantation oxidation layer formed before ion implantation, performing gate oxidation, and depositing a polysilicon layer;

3) performing lithography and etching to form a gate electrode of polysilicon;

4) implanting and activating dopants;

5) depositing metal such as Ni;

6) performing a first annealing so that Ni reacts with a portion of polysilicon;

7) selectively removing unreacted Ni;

8) performing a second annealing so that the whole gate electrode is converted into nickel silicide (i.e. a full silicidated metal gate electrode).

At step 1), a locally oxidized isolation is performed at about 1000° C., and an isolation layer has a thickness of about 3000-5000 angstroms, and a prior-implantation oxidation layer has a thickness of about 100-200 angstroms; doping ¹⁴N⁺ is performed with an implantation energy of about 10-30 Kev and an implantation dose of about 1×10¹⁴-6×10¹⁴ cm⁻².

At step 2), removing the prior-implantation oxidation layer formed before ion implantation comprises firstly rinsing in a mixed solution of H₂O:HF=9:1 by volume ratio, and then washing in a first etching solution for about 10 minutes, which is a mixed solution of H₂SO₄:H₂O₂=5:1 by volume ratio, and then washing in a second etching solution for about 5 minutes, which is a mixed solution of NH₄OH:H₂O₂:H₂O=0.8:1:5 by volume ratio, and then performing immersion in a mixed solution of hydrofluoric acid: isopropyl alcohol: water=0.2-0.7%:0.01-0.04%:1% by volume ratio at room temperature for about 5 minutes; depositing polysilicon layer is performed by chemical vapor deposition; a gate oxidation layer thus formed has a thickness of about 15-50 angstroms, and a polysilicon layer has thus formed has a thickness of about 1000-2000 angstroms.

At step 3), the polysilicon layer is patterned by reactive ion etching with photoresist having a thickness of about 1.5 microns as a mask, which etches away polysilicon in field region and leaves patterned polysilicon gate electrode.

At step 4), p-type dopants such as BF₂ are implanted for p-type field effect transistor, and n-type dopants such as As or P are implanted for n-type field effect transistor. When BF₂ is used as a p-type dopant, an implantation energy is about 15-30 Kev and an implantation dose is about 1×10¹⁵-5×10¹⁵ cm⁻². When As is used as an n-type dopant, an implantation energy is about 30-60 Kev and an implantation dose is about 1×10¹⁵-5×10¹⁵ cm⁻². When P is used as an n-type dopant, an implantation energy is about 40-60 Kev, and an implantation dose is about 1×10¹⁵-3×10¹⁵ cm⁻². The implanted dopants are activated at about 950-1020° C. for about 2-20 seconds.

At step 5), Ni is deposited to have a thickness of about 600-2000 angstroms.

At step 6), the first annealing is controlled in such a manner that one portion of polysilicon gate near a top surface reacts with Ni to form nickel silicide, but the other portion of polysilicon gate near its interface with a gate dielectric layer does not react with Ni. The first annealing is performed at about 340-390° C. for about 30-90 seconds.

At step 7), the unreacted Ni is removed by etching away in the first etching solution which is a mixed solution of H₂SO₄:H₂O₂=5:1 by volume ratio for about 20-30 minutes.

At step 8), the second annealing is controlled in such a manner that the remaining portions of polysilicon gate near its interface with a gate dielectric layer reacts with Ni to form nickel silicide, so that the whole volume of polysilicon gate is converted into nickel silicide and forms a full silicidation metal gate. The second annealing is performed at about 450-600° C. for about 30-90 seconds.

The inventive method has the following beneficial effects.

The inventive method forms metal silicide as the gate electrode of the metal complementary metal-oxide semiconductor device. Compared with the conventional method for manufacturing the metal gate electrode, the inventive method is much simpler, causes no pollution, and is easier to perform etching process.

The inventive method overcomes disadvantages of the one-step annealing process that forms a non-uniform silicide layer and introduces a linewidth effect.

The inventive method is simple compatible with the conventional CMOS processes, which can be easily integrated with the conventional CMOS process and has a promising prospect in application.

### BRIEF DESCRIPTION OF THE DRAWINGS

The invention will be described in connection with the drawings and embodiments.

FIG. 1 is a flow chart of the method for manufacturing a full silicidation metal gate with a two-step annealing process according to the present invention;

FIGS. 2 (a)-(f) are semiconductor structures at different stages of the method for manufacturing the full silicidation metal gate with the two-step annealing process according to the present invention;

in these figures, reference signs are as follows:
1—bulk silicon substrate;
2—gate dielectric layer;
3—polysilicon gate electrode;
4—STI;
5—dopants for ion implantation;
6—deposited Ni;
7—nickel suicide formed by reaction.

FIGS. 3 (a) and (b) show SEM images when a first annealing is performed at an excessively low temperature, in which FIG. 3 (a) shows an SEM image of a gate electrode after the first annealing at about 280° C. for about 60 seconds, and FIG. 3 (b) shows an SEM image of a gate electrode after a second annealing at about 530° C. for about 30 seconds.

FIGS. 4 (a) and (b) show SEM images when the first annealing is performed at an excessively high temperature, in which FIG. 4 (a) shows an SEM image of a gate electrode after the first annealing at about 410° C. for about 60 seconds, and FIG. 4 (b) shows an SEM image of a gate electrode after the second annealing at about 530° C. for about 30 seconds.

FIGS. 5 (a) and (b) show SEM images when the first annealing is performed at a suitable temperature, in which FIG. 5 (a) shows an SEM image of a gate electrode after the first annealing at about 360° C. for about 60 seconds, and FIG. 5 (b) shows an SEM image of a gate electrode after the second annealing at about 530° C. for about 30 seconds.

### DETAILED DESCRIPTION OF PREFERRED EMBODIMENTS

The invention will be further illustrated in detail in the following embodiments in conjunction with the accompanying drawings, so that the object, solution and advantages of the present invention are apparent.

The present invention provides a method for manufacturing a full silicidation metal gate which is used in complementary Metal-Oxide-Semiconductor (CMOS) Devices and circuits (VLSI) in ultra-deep submicron technology, comprising the steps of depositing Ni and performing two-step rapid thermal annealing (RTA) so that Ni reacts with polysilicon completely to form the full silicidation metal gate.

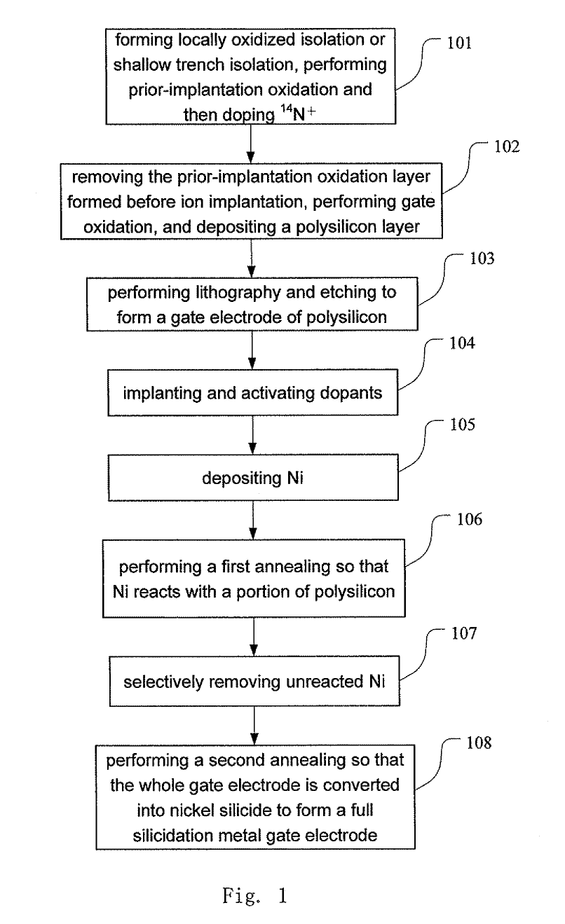

FIG. 1 shows a flow chart of the method for manufacturing the full silicidation metal gate with two-step annealing according to the present invention. The method comprises the following steps.

Step 101: locally oxidized isolation or shallow trench isolation is formed at about 1000° C., and the isolation layer has a thickness of about 3000-5000 angstroms; forming a prior-implantation oxidation layer to have a thickness of about 100-200 angstroms; ¹⁴N⁺ implanting is performed with an implantation energy of about 10-30 Kev and an implantation dose of about 1×10¹⁴-6×10¹⁴ cm⁻².

Step 102: removing the prior-implantation oxidation layer formed by ion implantation, performing gate oxidation, and depositing polysilicon layer.

At this step, removing the prior-implantation oxidation layer formed by ion implantation comprises firstly rinsing in a mixed solution of H₂O:HF=9:1 by volume ratio, and then washing in a first etching solution for about 10 minutes, which is a mixed solution of H₂SO₄:H₂O₂=5:1 by volume ratio, and then washing in a second etching solution for about 5 minutes, which is a mixed solution of NH₄OH:H₂O₂:H₂O=0.8:1:5 by volume ratio, and then performing immersion in a mixed solution of hydrofluoric acid: isopropyl alcohol: water=0.2-0.7%:0.01-0.04%:1% by volume ratio at room temperature for about 5 minutes.

A gate oxidation layer thus formed has a thickness of about 15-50 angstroms. A polysilicon layer is deposited by low-pressure chemical vapor deposition (LPCVD) to have a thickness of about 1000-2000 angstroms.

Step 103: patterning a polysilicon gate by lithography followed by etching.

At this step, the lithography is performed with the photoresist (for example, 9918 photoresist) having a thickness of about 1.5 microns as a mask, the polysilicon layer is etched by reactive ion etching to remove the polysilicon in the field region and form the polysilicon gate electrode.

Step 104: implanting and activating dopants.

At this step, p-type dopants such as BF₂ are implanted for a p-type field effect transistor, and n-type dopants such as As or P are implanted for an n-type field effect transistor. When BF₂ is used as the p-type dopant, an implantation energy is about 15-30 Kev and an implantation dose is about 1×10¹⁵-5×10¹⁵ cm⁻². When As is used as the n-type dopant, an implantation energy is about 30-60 Kev and an implantation dose is about 1×10¹⁵-5×10¹⁵ cm⁻². When P is used as the n-type dopant, an implantation energy is about 40-60 Kev, and an implantation dose is about 1×10¹⁵-3×10¹⁵ cm⁻². The implanted dopants are activated at about 950-1020° C. for about 2-20 seconds

Step 105: depositing a metal such as Ni.

At this step, Ni is deposited to have a thickness of about 600-2000 angstroms.

Step 106: performing a first annealing so that a portion of polysilicon reacts with Ni.

At this step, the first annealing is performed at about 340-390° C. for about 30-90 seconds.

Step 107: selectively removing unreacted Ni.

At this step, the unreacted Ni is etched away in the first etching solution which is a mixed solution of H₂SO₄:H₂O₂=5:1 by volume ratio for about 20-30 minutes.

Step 108: performing a second annealing so that of the whole gate electrode is converted into nickel silicide to form the full silicidation metal gate electrode. At this step, the second annealing is performed at about 450-600° C. for about 30-90 seconds.

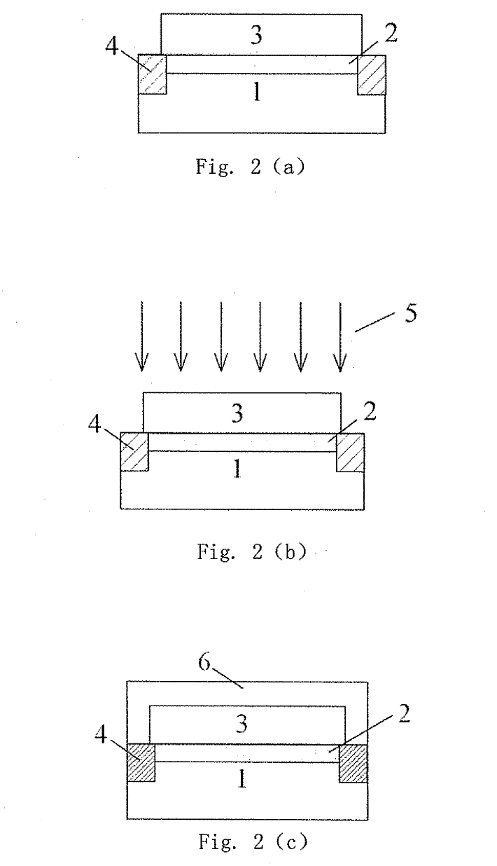

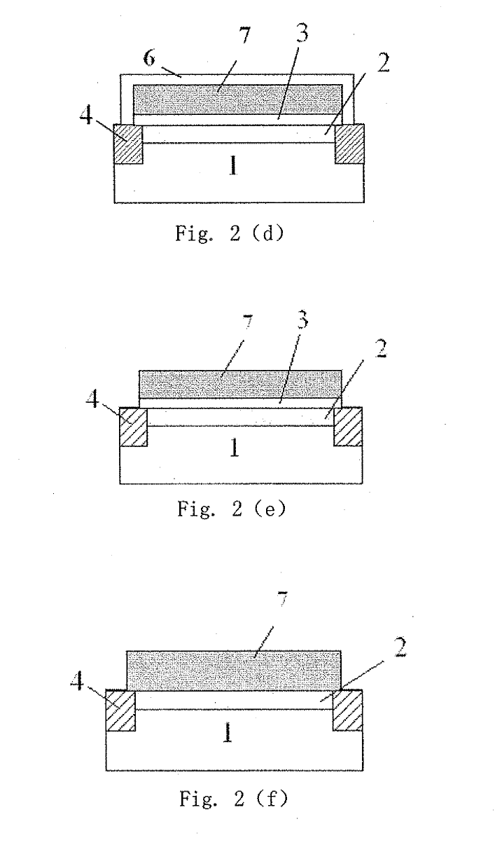

FIGS. 2 (a)-(f) are semiconductor structures at different stages of the method for manufacturing the full silicidation metal gate with two-step annealing according to the present invention, including (a) a schematic view of the semiconductor structure after deposition of polysilicon, lithography and etching; (b) a schematic view of the semiconductor structure after ion implantation and activation annealing; (c) a schematic view of the semiconductor structure after deposition of Ni; (d) a schematic view of the semiconductor structure after a first annealing; (e) a schematic view of the semiconductor structure after selective removal of unreacted Ni; (f) a schematic view of the semiconductor structure after a second annealing. One example of the invention is given as follows.

Step 1: performing field oxidation at about 1000° C. to have a thickness of about 3000-5000 angstroms;

Step 2: forming a prior-implantation oxidation layer to have a thickness of about 100-200 angstroms;

Step 3: implanting ¹⁴N⁺ with an implantation energy of about 10-30 Kev and an implantation dose of about 1×10¹⁴-6×10¹⁴ cm⁻²;

Step 4: removing the prior-implantation oxidation layer formed by ion implantation in a mixed solution of H₂O:HF=9:1;

Step 5: washing in a first etching solution for about 10 minutes, and then washing in a second etching solution for about 5 minutes, and then performing immersion in a mixed water solution of hydrofluoric acid/isopropyl alcohol (IPA) at the room temperature for about 5 minutes;

Step 6: performing gate oxidation to have a thickness of about 15-50 angstroms;

Step 7: depositing polysilicon by LPCVD to have a thickness of about 2000 angstroms;

Step 8: patterning the polysilicon with the photoresist (for example 9918 photoresist) having a thickness of about 1.5 microns as the mask;

Step 9: etching the polysilicon layer by reactive ion etching to etch away the polysilicon in the field region;

Step 10: implanting As into the gate with an implantation energy of about 10-50 Kev and an implantation dose of about 1×10¹⁵-5×10¹⁵ cm⁻²;

Step 11: activating dopants at about 950-1020° C. for about 2-20 seconds;

Step 12: depositing Ni to have a thickness of about 1400 angstroms;

Step 13: performing a first rapid thermal annealing (RTA) at about 360° C. for about 60 seconds;

Step 14: selectively removing unreacted Ni in the first etching solution which is a mixed solution of H₂SO₄:H₂O₂=5:1 by volume ratio for about 20-30 minutes;

Step 15: performing a second rapid thermal annealing (RTA) at about 530° C. for about 30 seconds.

It is critical in the present invention that conditions of the first annealing needs to be well controlled. If the annealing temperature is excessively high or the annealing time is excessively long in the first annealing, the gate electrode will be fully silicided in the first annealing. If the annealing temperature is excessively low in the first annealing, the polysilicon will react insufficiently and the gate electrode will not be fully silicided in the second annealing. Consequently, the polysilicon gate electrode is not of full silicidation. The suitable annealing condition is that some portions of the polysilicon gate near the gate dielectric layer does not react with Ni in the first annealing, but is fully silicided in the second annealing.

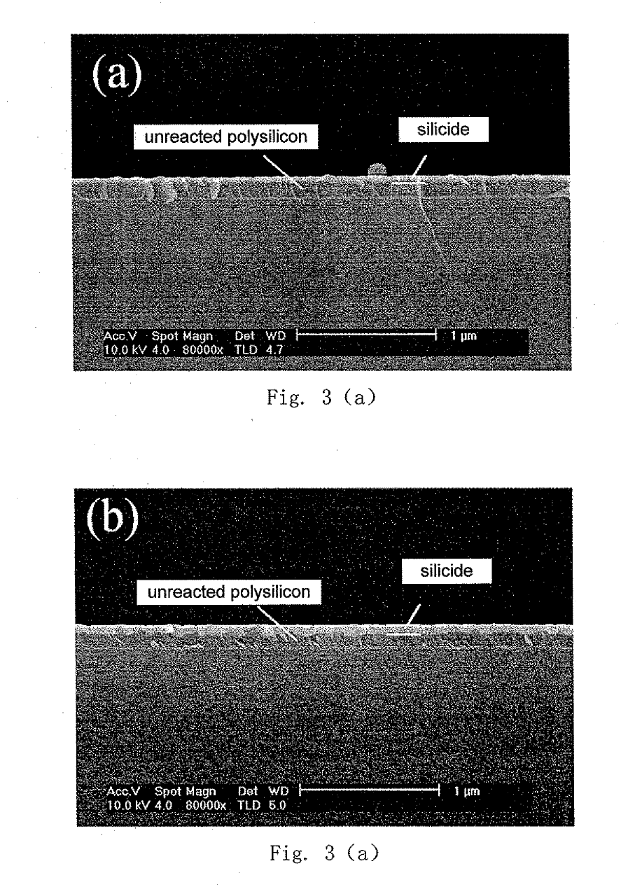

FIG. 3 shows an SEM image of the gate electrode when the annealing temperature is excessively low in the first annealing. As shown in FIG. 3 (a), when the annealing temperature is excessively low in the first annealing (at about 280° C. for about 60 seconds), only a portion of polysilicon near the top surface of the gate electrode reacts with Ni to form silicide, but most of polysilicon does not. As shown in FIG. 3 (b), the thickness of silicide increases after the second annealing (at about 530° C. for about 30 seconds), but most of polysilicon has still not reacted with Ni to form silicide. The gate electrode is not of full silicidation.

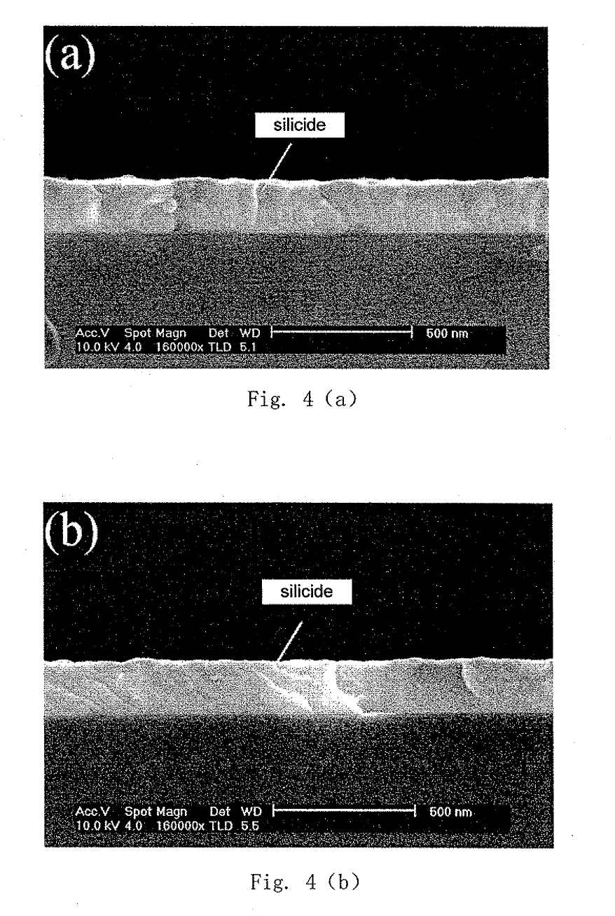

FIG. 4 shows an SEM image of the gate electrode when the annealing temperature is excessively high in the first annealing. As shown in FIG. 4 (a), when the annealing temperature is excessively high in the first annealing (at about 410° C. for about 60 seconds), the whole polysilicon gate is converted into silicide in the first annealing. As shown in FIG. 4 (b), the roughness of silicide is improved after the second annealing (at about 530° C. for about 30 seconds), but an excessive amount of Ni will diffuse into the gate dielectric layer and deteriorate the performance of the is device.

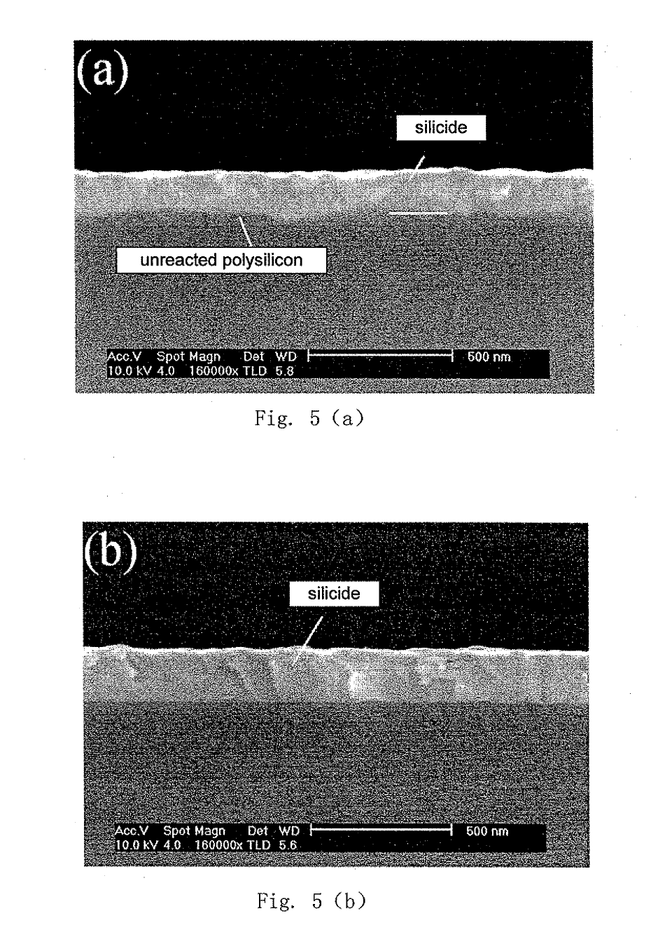

FIG. 5 shows an SEM image of the gate electrode when the annealing temperature is suitable in the first annealing. As shown in FIG. 5 (a), one portion of polysilicon near the top surface is converted into silicide, but other portions of polysilicon near the gate dielectric do not react with Ni to form silicide after the first annealing (at about 360° C. for about 60 seconds). As shown in FIG. 5 (b), the whole the gate electrode is converted into silicide to form a full silicidation metal gate in the second annealing (at about 530° C. for about 30 seconds).

While the invention has been described with reference to specific embodiments, the description is illustrative of the invention and is not to be considered as limiting the invention. Various modifications and applications may occur for those skilled in the art without departing from the true spirit and scope of the invention as defined by the appended claims.

What is claimed is:

1. A method for manufacturing a full silicidation metal gate, comprising steps of:
1) forming locally oxidized isolation or shallow trench isolation, performing prior-implantation oxidation and then doping ¹⁴N⁺;
2) removing the prior-implantation oxidation layer formed before ion implantation, performing gate oxidation, and depositing a polysilicon layer;
3) performing lithography and etching to form a gate electrode of polysilicon;
4) implanting and activating dopants;
5) depositing Ni;
6) performing a first annealing so that Ni reacts with a portion of polysilicon;
7) selectively removing unreacted Ni;
8) performing a second annealing so that the whole gate electrode is converted into nickel silicide to form a full silicidation metal gate electrode.

2. The method according to claim 1, wherein in step 1),
the locally oxidized isolation is performed at about 1000° C., and the isolation has a thickness of about 3000-5000 angstroms, and the prior-implantation oxidation layer has a thickness of about 100-200 angstroms; doping ¹⁴N⁺ is performed with an implantation energy of about 10-30 Kev and an implantation dose of about 1×10¹⁴-6×10¹⁴ cm⁻².

3. The method according to claim 1, wherein in step 2),
removing the prior-implantation oxidation layer formed before ion implantation comprises firstly rinsing in a mixed solution of H₂O:HF=9:1 by volume ratio, and then washing in a first etching solution for about 10 minutes, which is a mixed solution of H₂SO₄:H₂O₂=5:1 by volume ratio, and then washing in a second etching solution for about 5 minutes, which is a mixed solution of NH₄OH:H₂O₂:H₂O=0.8:1:5 by volume ratio, and then performing immersion in a mixed solution of hydrofluoric acid: isopropyl alcohol: water=0.2-0.7%:0.01-0.04%:1% by volume ratio at room temperature for about 5 minutes;
when performing gate oxidation, a gate oxidation layer thus formed has a thickness of about 15-50 angstroms; when depositing polysilicon layer, the polysilicon layer is deposited by chemical vapor deposition to have a thickness of about 1000-2000 angstroms.

4. The method according to claim 1, wherein in step 3), a lithography is performed with the photoresist having a thickness of about 1.5 microns as a mask, and the polysilicon in the field region is etched away by reactive ion etching to form the gate electrode of polysilicon.

5. The method according to claim 1, wherein in step 4), p-type dopants such as BF₂ are implanted for a p-type field effect transistor, and n-type dopants such as As or P are implanted for an n-type field effect transistor,
wherein BF₂ is used as the p-type dopant and implanted under an implantation energy of about 15-30 Kev and an implantation dose of about 1×10¹⁵-5×10¹⁵ cm⁻²;
wherein As is used as the n-type dopant and implanted under an implantation energy of about 30-60 Kev and an implantation dose of about 1×10¹⁵-5×¹⁵ cm⁻²;
wherein P is used as the n-type dopant and implanted under an implantation energy of about 40-60 Kev and an implantation dose of about 1×10¹⁵-3×¹⁵ cm⁻²; and
wherein the dopants are activated at about 950-1020° C. for about 2-20 seconds.

6. The method according to claim 1, wherein in the step 5), Ni is deposited to have a thickness of about 600-2000 nanometers.

7. The method according to claim 1, wherein in the step 6), the first annealing is controlled in such a manner that one portion of the polysilicon on the top surface of the polysilicon gate electrode reacts with Ni to form nickel silicide, but some portions of the polysilicon near the gate dielectric layer does not react with Ni, and the first annealing is performed at about 340-390° C. for about 30-90 seconds.

8. The method according to claim 1, wherein in the step 7), the unreacted Ni is removed by etching away in the first etching solution which is a mixed solution of H₂SO₄:H₂O₂=5:1 by volume ratio for about 20-30 minutes.

9. The method according to claim 1, wherein in the step 8), the second annealing is controlled in such a manner that the remaining portions of the polysilicon near the gate dielectric layer reacts with Ni to form nickel silicide, so that the whole gate electrode is converted into nickel silicide and forms a full silicidation metal gate, and the second annealing is performed at about 450-600° C. for about 30-90 seconds.
